(19) United States
(12) Patent Application Publication
(10) Pub. No.: US 2006/0249829 A1
(43) Pub. Date: Nov. 9, 2006

(54) Stacked type semiconductor device

(76) Inventors: Mitsuaki Katagiri, Tokyo (JP); Masanori Shibamoto, Tokyo (JP); Tsutomu Hara, Tokyo (JP); Koichiro Aoki, Tokyo (JP); Naoya Kanda, Tokyo (JP); Shuji Kikuchi, Tokyo (JP); Hisashi Tanie, Tokyo (JP)

Correspondence Address: MCDERMOTT WILL & EMERY LLP, 600 13TH STREET, N.W., WASHINGTON, DC, 20005-3096, US

(21) Appl. No.: 11/399,608

(22) Filed: Apr. 7, 2006

(30) Foreign Application Priority Data
Apr. 8, 2005 (JP) 2005-112902

(51) Int. Cl. H01L 23/02

(52) U.S. Cl. 257/686

(57) ABSTRACT

A stacked type semiconductor device comprising: a baseboard having a terminal row formed at an end in which connecting terminals is arranged linearly and having a wiring pattern connected to the connecting terminals and external terminals; semiconductor chips having a pad row in which pads is arranged linearly in parallel to the terminal row and being stacked on the baseboard; and interposer boards having a wiring layer including a plurality of wires arranged in parallel with the same length for connecting between pads of the pad row and connecting terminals of the terminal row.

### BACKGROUND OF THE INVENTION

1. Field of the Invention

The present invention relates to a technical field of a stacked type semiconductor device having a structure in which a plurality of semiconductor chips is arranged.

2. Description of the Related Art

In recent years, a further increase in the capacity of a semiconductor memory such as DRAM has been demanded in order to achieve higher performance of apparatuses. Construction of the semiconductor memory on a single semiconductor chip requires finer microfabrication as its capacity increases, and it is possible that the yield deteriorates. Thus, a stacked type semiconductor device having a structure in which a plurality of semiconductor chips is stacked on a baseboard has been proposed. For example, by stacking a plurality of DRAM chips and an interface chip for controlling data input/output of each DRAM chip on the baseboard, a stacked type memory with a small size and large capacity capable of being controlled from outside similar to a single DRAM can be realized.

Generally, construction of the stacked type memory having the above-described stacked structure requires an interposer board which serves as a junction circuit for connecting each DRAM chip with the interface chip. For miniaturization and higher density of the stacked type memory, the structure of the interposer board needs to be thin and small and the efficiency of wiring needs to be increased. Further, to obtain a structure which allows bending of the interposer board by increasing the degree of freedom of disposition of the interposer board, the stiffness of the interposer board needs to be reduced.

A specific configuration of a conventional stacked type semiconductor device has been disclosed in, for example, Japanese Patent Application Laid-Open No. 2001-110978. In an example disclosed in the Japanese Patent Application Laid-Open No. 2001-110978, a plurality of semiconductor chips is stacked on the board and the interposer board using a flexible board is placed on the side of the semiconductor chip. By employing such a structure, the interposer board can be placed in a state in which it is bent freely, so that wiring for transmitting signals between the plurality of DRAM chips and the interface chip can be formed on the interposer board.

Stacking a number of semiconductor chips as described above allows transmission of multiple signals through the interposer board, and a wiring structure capable of high speed transmission of signals is required in order to adapt the increasing speed of the semiconductor memory in recent years. However, when the interposer board is formed of, for example, a flexible board or the like, a multilayer circuit board cannot be used from the viewpoints of the low stiffness and cost, and it is difficult to achieve a wiring structure suitable for high speed signal transmission. Thus, impedance mismatching and distortion of transmission waveform occurs in transmission of signals thereby possibly leading to deterioration of noise immunity performance of the semiconductor memory.

When a number of interposer boards are provided corresponding to a number of semiconductor chips, a sufficient space for disposing the interposer boards around the semiconductor chip is required. As a result, the wiring efficiency of the interposer boards drops, so that the size of the semiconductor chip cannot be increased due to restriction of the size of the baseboard.

### BRIEF SUMMARY OF THE INVENTION

An object of the present invention is to provide a stacked type semiconductor device which achieves a wiring structure suitable for high speed signal transmission to improve noise immunity performance even if a number of interposer boards are provided by stacking a number of semiconductor chips, and improves wiring efficiency and space usage efficiency;

An aspect of the present invention is a stacked type semiconductor device, comprising: a baseboard having a terminal row formed at an end in which a plurality of connecting terminals is arranged linearly and having a wiring pattern electrically connected to said plurality of connecting terminals and external terminals; one or more semiconductor chips having a pad row in which a plurality of pads is arranged linearly in approximately parallel to said terminal row and being stacked on said baseboard; and one or more interposer boards having a wiring layer including a plurality of wires arranged approximately in parallel with an approximately same length for electrically connecting between each pad of said pad row and each connecting terminal of said terminal row.

According to an aspect of the present invention, the interposer board serves as a junction circuit for connecting the baseboard to the semiconductor chips, and electrically connects between the pad row of the semiconductor chip and the terminal row at an end of the baseboard using a plurality of wires approximately in parallel with an approximately the same length. Since the pad row of the semiconductor chip is arranged in approximately parallel to the terminal row of the baseboard, the wiring structure of the interposer board is electrically balanced to be suitable for high-speed signal transmission. Accordingly, a stacked type semiconductor device can be realized, in which excellent noise immunity performance is obtained by preventing impedance mismatching and distortion of transmission waveform in signal transmission, and wiring efficiency and space usage efficiency are improved.

In the present invention, a flexible board which is formed by combining base material made of resin and said wiring layer may be used as said interposer board. Therefore, the stiffness of the interposer board can be reduced so that the inter poser board obtains structural freedom in arrangement such as bending, as well as obtaining excellent noise immunity performance.

In the present invention, said semiconductor chip may have a rectangular shape and said pad row may be arranged in parallel with a long side direction of said rectangular shape at an approximate center position of said semiconductor chip. Therefore, particularly when the semiconductor chip having the center pad structure is used, excellent space usage efficiency can be obtained as well as excellent noise immunity performance.

In the present invention, said interposer board may extend from a position of said pad row to one long side of said semiconductor chip.

In the present invention, said plurality of wires may include one or more signal wires, one or more power supply wires and one or more ground wires each connected to a circuit of said semiconductor chip.

In the present invention, said signal wire of said interposer board may be formed to be a transmission line having a coplanar structure.

In the present invention, said plurality of wires may be arranged so that a pair of adjacent wires composed of said power supply wire and said ground wire is adjacent to said signal wire.

In the present invention, an arrangement pattern of said plurality of wires may be a pattern in an order of said signal wire, said power supply wire, said ground wire and said signal wire as a repeating unit, and said plurality of pads of said pad row is arranged according to said arrangement pattern.

According to the above described aspects, by appropriately arranging the plurality of wires on the interposer board, an effective wiring structure capable of maintaining an electrically balanced state in high-speed signal transmission is achieved, thereby further improving noise immunity performance.

Meanwhile, the present invention may comprise a plurality of said semiconductor chips, and further comprise a plurality of said interposer boards corresponding to a whole or a part of said plurality of semiconductor chips, wherein a plurality of said terminal row corresponding to said plurality of interposer boards respectively may be formed on said baseboard, and wherein said plurality of interposer boards may be arranged in a positional relation in which the nearer said corresponding semiconductor chip is to said baseboard in a stacking direction, the nearer said corresponding terminal row is to an inside of said baseboard in a planar direction.

In the present invention, said semiconductor chip may be stacked in a face-up structure and said interposer board may be arranged so that said wiring layer is opposite to a surface of said semiconductor chip.

In the present invention, a plurality of DRAM chips each having said pad row of a center pad structure may be stacked on said baseboard, and an interface chip for controlling data input/output of each said DRAM chip may be stacked between said baseboard and said plurality of DRAM chips.

In the present invention, wherein said interface chip and said plurality of DRAM chips may be connected to each other in a bus type connection form.

As described above, according to the present invention, the stacked type semiconductor device is constructed by stacking the semiconductor chips on the baseboard, connecting between the pad row of each semiconductor chip and the terminal row of the baseboard with an interposer board having a plurality of wires with approximately the same length arranged approximately in parallel, and arranging the pad row and the terminal row approximately in parallel. Thus, a wiring structure suitable for high-speed signal transmission can be achieved. As a consequence, noise immunity performance of the semiconductor memory device can be improved, and wiring efficiency and space usage efficiency can be increased.

### BRIEF DESCRIPTION OF THE DRAWINGS

The above and other objects and features of the invention will appear more fully hereinafter from a consideration of the following description taken in connection with the accompanying drawing wherein one example is illustrated by way of example, in which;

FIG. 1 is an exploded perspective view of the stacked type memory device of a first embodiment;

FIG. 2 is a sectional structural view of the stacked type memory device of the first embodiment;

FIGS. 3A and 3B are diagrams showing planar shape and terminal arrangement of the interposer board and the baseboard of the stacked type memory device of the first embodiment

FIG. 4 is a schematic diagram showing connection configuration of the stacked type memory of the first embodiment;

FIG. 5 is a sectional structural view of the stacked type memory device of a second embodiment;

FIG. 6 is a diagram showing a terminal arrangement of the baseboard of the stacked type memory device of the second embodiment;

FIG. 7 is a schematic diagram showing connection configuration of the stacked type memory of the second embodiment;

FIG. 8 is a sectional structural view of a first comparative example;

FIG. 9 is a sectional structural view of a second comparative example;

FIGS. 10A and 10B are diagrams explaining the effect of the wiring structure of this embodiment in a state in which the plurality of wires has a corner portion halfway;

FIGS. 11A to 11D are diagrams explaining the effect of the wiring structure of this embodiment in a state in which the plurality of wires has a branch portion halfway;

FIG. 12 is a diagram showing optimized arrangement pattern of the plurality of wires on the pad row and its periphery;

FIG. 13 is a diagram showing an example of arrangement pattern without optimization of this embodiment for comparison with FIG. 12; FIG. 14 is a view showing an example of the transmission line having the coplanar structure;

FIGS. 15A and 15B are diagrams showing an analysis result of the operating waveform by simulation signal in order to confirm the effect of the bus type connection form of this embodiment;

FIG. 16 is a diagram explaining the reason of stacking the DRAM chips in the face-down structure as implementation condition of the stacked type memory of this embodiment;

FIG. 17 is a block diagram of the memory module using the stacked type memories of this embodiment; and

FIGS. 18 and 18 are plane and side views of the memory module using the stacked type memories of this embodiment.

### DETAILED DESCRIPTION OF THE INVENTION

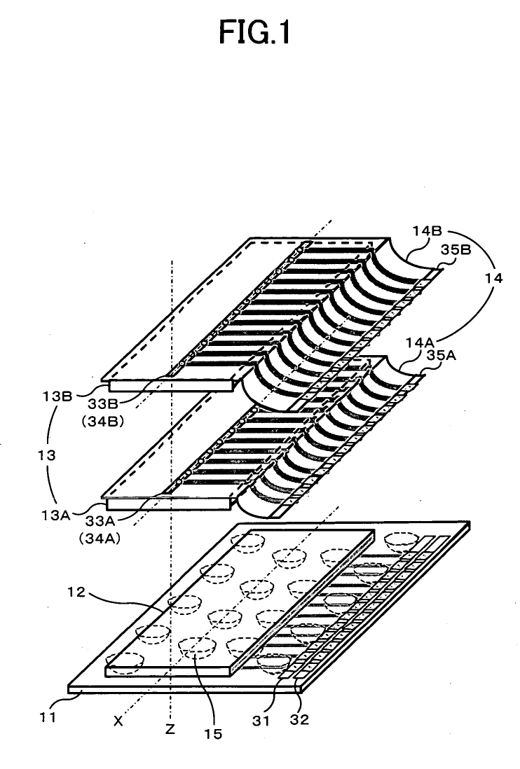

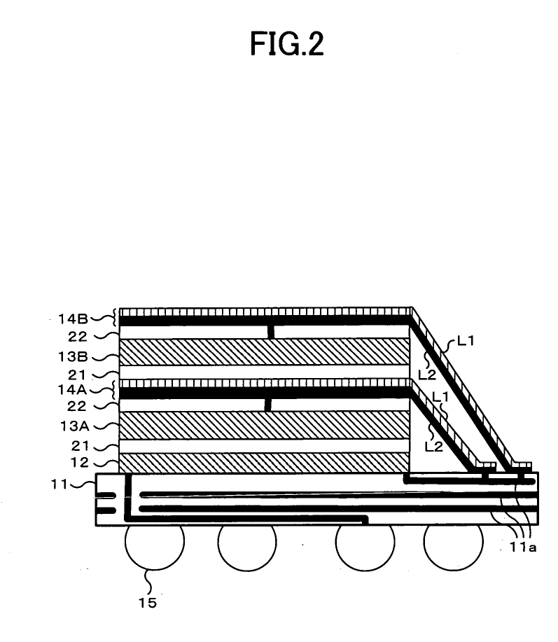

Hereinafter, the preferred embodiments of the present invention will be described with reference to the accompanying drawings. In this embodiment, as an example of a stacked type semiconductor device to which the present invention is applied, a stacked type memory constructed by stacking a plurality of DRAM chips will be described. Here, regarding the stacked type memory of this embodiment, two embodiments having different numbers of the stacked DRAM chips will be described. First, as a first embodiment, a basic structure of the stacked type memory constructed by stacking two DRAM chips will be described. As diagrams for explaining the structure of the stacked type memory of the first embodiment, FIG. 1 shows an exploded perspective view and FIG. 2 shows a sectional structural view.

As shown in FIGS. 1 and 2, the stacked type memory of the first embodiment has a structure in which three semiconductor chips are stacked on the baseboard 11. The semiconductor chips to be stacked include an interface chip 12 for controlling input/output signals and two DRAM chips 13 each having a predetermined memory capacity in order from the bottom layer. And, two interposer boards 14 for making electrical connection between the DRAM chips 13 and the baseboard 11 are provided. The two DRAM chips 13 include a lower DRAM chip 13A and an upper DRAM chip 13B, and the two interposer boards 14 include an interposer board 14A connected to the lower DRAM chip 13A and an interposer board 14B connected to the upper DRAM chip 13B.

A number of solder balls 15 as external terminals used for connection to outside are attached to the bottom face of the baseboard 11. The baseboard 11 is a multilayer circuit board on which a wiring pattern 11a (FIG. 2) connected to the interface chip 12, the interposer boards 14 and the solder balls 15. The interface chip 12 is mounted on the top face of the baseboard 11 with its front surface facing downward (face-down structure). Flip-chip connection technology is used for connecting the baseboard 11 and the interface chip 12. That is, solder bumps (not shown) are formed at positions corresponding to pads on the bottom face of the interface chip 12 and connected to the wiring pattern 11a through electrodes of the baseboard 11.

Since the baseboard 11 is formed of, for example, glass epoxy resin and the interface chip 12 is formed of silicone, resin (not shown) is filled in a gap between the baseboard 11 and the interface chip 12 in order to absorb stress due to the difference in thermal expansion therebetween.

The lower DRAM chip 13A is stacked over the interface chip 12 through an adhesive layer 21 with its front surface facing upward (face-up structure). The interposer board 14A is placed over the DRAM chip 13A through a filler 22. The upper DRAM chip 13B is stacked over the interposer board 14A through the adhesive layer 21 with face-up structure like the lower DRAM chip 13A. The interposer board 14B is placed over the DRAM chip 13B through the filler 22.

The two DRAM chips 13 have rectangular shapes and include a pad row 33 including a plurality of pads connected to electrodes in the chip. This pad row 33 is located in the center portion of the chip along the long side direction of the DRAM chip 13 based on a center pad structure adopted generally for the DRAM chips 13.

As the interposer board 14, a flexible board in which base material L1 made of resin such as polyimide and a wiring layer L2 are combined is used and placed on the DRAM chip 13 so that the wiring layer L2 faces downward. To electrically connect the wiring layer L2 of the interposer board 14 and the pad row 33 of the DRAM chip 13, for example, COF connection is used. This COF connection is a technique to connect bumps provided on the pad row 33 of the DRAM chip 13 with a terminal row provided on the surface of the interposer board 14 using ultrasonic wave or the like. Meanwhile, specific role and wiring structure of the interposer board 14 will be described in detail later.

The interposer board 14 has a rectangular shape larger than the DRAM chip 13 in size and covers the entire DRAM chip 13. As shown in FIG. 2, the interposer board 14 extends from an end of the DRAM chip 13, is bent downward, and is attached to the baseboard 11. A terminal row 31 for electrically connecting the wiring layer L2 of the lower interposer board 14A and a terminal row 32 for electrically connecting the wiring layer L2 of the upper interposer board 14B are formed at an end of the top face of the baseboard 11. By such a structure, it is possible to make a connection in the DRAM chip 13 from the pad row 33 through the interposer board 14 and further through the terminal rows 31 and 32 and the wiring pattern 11a to the interface chip 12.

In addition, the entire stacked type memory is filled with material made of resin, in a state where the interface chip 12 and the two DRAM chips 13 are stacked on the baseboard 11 and the two interposer boards 14 are provided, so that the stacked type memory is protected from an external environment.

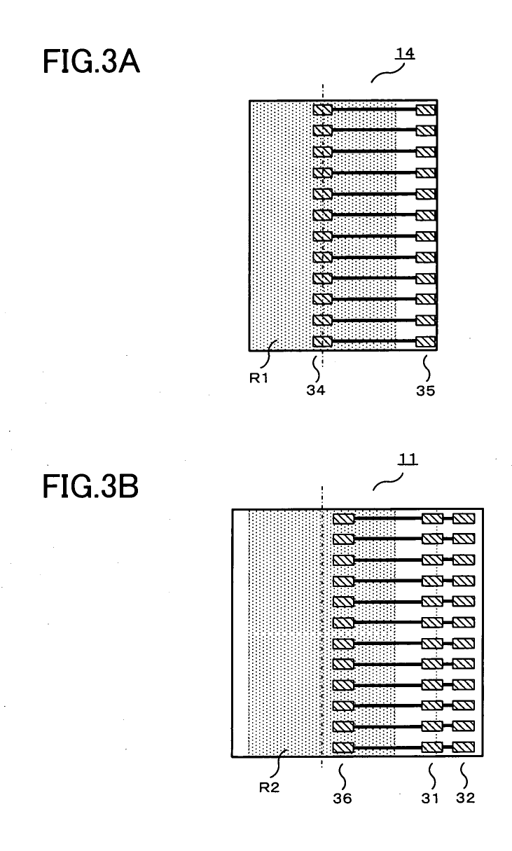

Terminals and wiring structures of the interposer board 14 and the baseboard 11 will be described in detail with reference to FIGS. 3A and 3B. FIG. 3A shows a planar shape and terminal arrangement of the interposer board 14. The lower interposer board 14A and the upper interposer board 14B have the planar shape and the terminal arrangement shown in FIG. 3A. An area R1 of the interposer board 14 with which the DRAM chips 13 overlap in the stacking direction (Z direction in FIG. 1) is shown and a terminal row 34 in which a plurality of connecting terminals is arranged linearly at a predetermined pitch is formed in the center. The terminal row 34 is arranged in parallel with the long side direction of the DRAM chip 13 and formed so that each terminal is placed at the same position as each pad of the pad row 33 of the DRAM chip 13.

A terminal row 35 including a plurality of connecting terminals is formed at an end of the interposer board 14 like the terminal row 34. Corresponding connecting terminals between these two terminal rows 34 and 35 are connected with each other by a plurality of wires arranged in parallel with a predetermined length and at a predetermined pitch. Each of the wires extending from the terminal row 34 to the terminal row 35 is bent in the vicinity of the boundary of the area R1 and arranged having an inclined portion leading to the terminal row 31 on the baseboard 11 as shown in FIG. 2. Meanwhile, on the interposer board 14, two terminal rows are also formed in the same shape and arrangement.

FIG. 3B shows a planar shape and terminal arrangement of the top face of the baseboard 11. An area R2 of the baseboard 11 with which the DRAM chips 13 overlap in the stacking direction (Z direction in FIG. 1) is shown. The above-described two terminal rows 31 and 32 formed at the end of the baseboard 11 are arranged so that the terminal row 31 is placed inside, as seen from the center of the baseboard 11, and the terminal row 32 is placed outside. Such an arrangement is a result of considering the positional relation of the respective inclined portions of the lower interposer board 14A and the upper interposer board 14B. Further, a terminal row 36 including a plurality of connecting terminals connected to the bottom face of the interface chip 12 is formed at a position near the center of the baseboard 11.

The corresponding connecting terminals of the three terminal rows 31, 32 and 36 formed on the baseboard 11 are connected one to one by a plurality of wires formed as part of the wiring pattern 11a. This plurality of wires is arranged at the same pitch and in the same direction as the plurality of wires of the interposer board 14. In the first embodiment, the pad row 33 of each of two DRAM chips 13, the terminal rows 34 and 35 of the interposer boards 14 and the terminal rows 31, 32 and 36 on the baseboard 11 are parallel to each other in the same direction as the long side direction of the DRAM chip 13. On the other hand, the wires connecting each pad or each terminal are parallel to each other and the same length, and extend in a direction perpendicular to the long side direction of the DRAM chip 13.

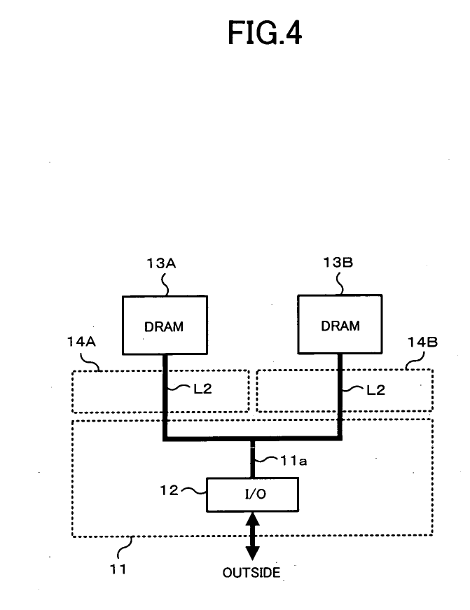

FIG. 4 is a schematic diagram showing a connection configuration of the stacked type memory of the first embodiment. In FIG. 4, bus type connection form is adopted between the interface chip 12 and each DRAM chip 13. The interface chip 12 is connected to outside through the solder balls 15 and the wiring pattern 11a of the baseboard 11. Further, the interface chip 12 is connected from the wiring pattern 11a of the baseboard 11 branching into two directions through the two interposer boards 14 to the two DRAM chips 13.

A control signal to the DRAM chip 13 is generated in the interface chip 12 based on a signal input from outside. The interface chip 12 supplies write data from outside to the DRAM chips 13 and outputs read data from the DRAM chip 13 to outside. In this case, in each of the two DRAM chips 13, a chip select terminal (not shown) are provided so as to enable distribution of a variety of signals to the interface chip 12.

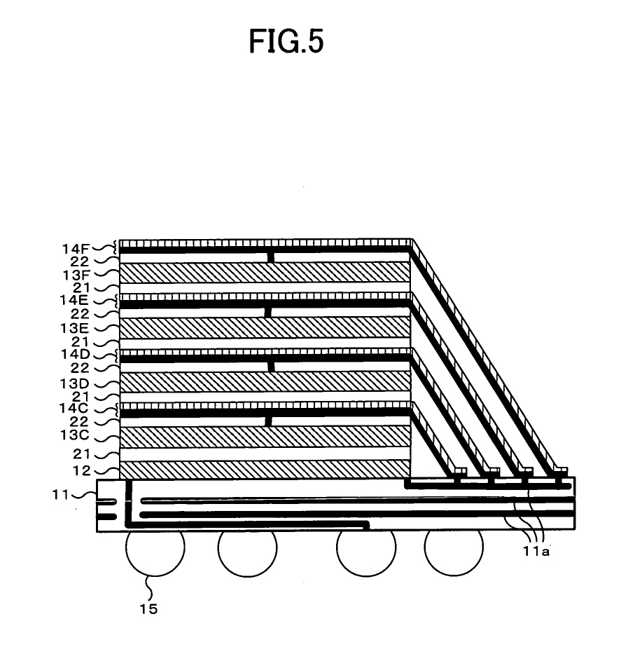

Next, as a second embodiment, a basic structure of the stacked type memory constructed by stacking four DRAM chips will be described. FIG. 5 is a sectional structural view of the second embodiment which corresponds to FIG. 2 of the first embodiment. The stacked type memory of the second embodiment shown in FIG. 5 has a structure in which the interface chip 12 and four DRAM chips 13 are stacked on the baseboard 11 and four interposer boards 14 are provided. The four DRAM chips 13 include a first layer DRAM chip 13C, a second layer DRAM chip 13D, a third layer DRAM chip 13E and a fourth layer DRAM chip 13F. And a first interposer board 14C, a second interposer board 14D, a third interposer board 14E and a fourth interposer board 14F are connected to the four DRAM chips 13 respectively in this order from the bottom layer.

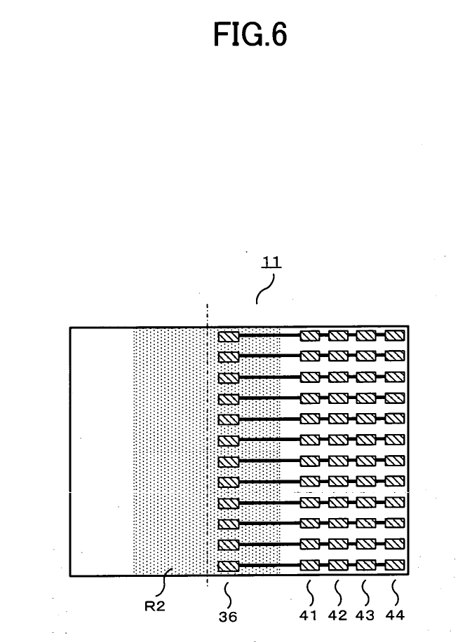

FIG. 6 shows terminal arrangement of the baseboard 11 of the second embodiment. The arrangement of FIG. 6 is different from FIG. 3B of the first embodiment in that four terminal rows 41 to 44 are arranged in parallel at an end of the baseboard 11. As seen from the center of the baseboard 11, a terminal row 41 corresponding to the first interposer 14C, a terminal row 42 corresponding to the second interposer 14D, a terminal row 43 corresponding to the third interposer board 14E and a terminal row 44 corresponding to the fourth interposer board 14F are formed in this order from inside to outside. In this manner, the nearer the baseboard 11 and the interposer board 14 to each other on the baseboard 11 (the lower the interposer board 14 is placed), the nearer the corresponding terminal rows 41 to 44 are to the inside of the baseboard 11.

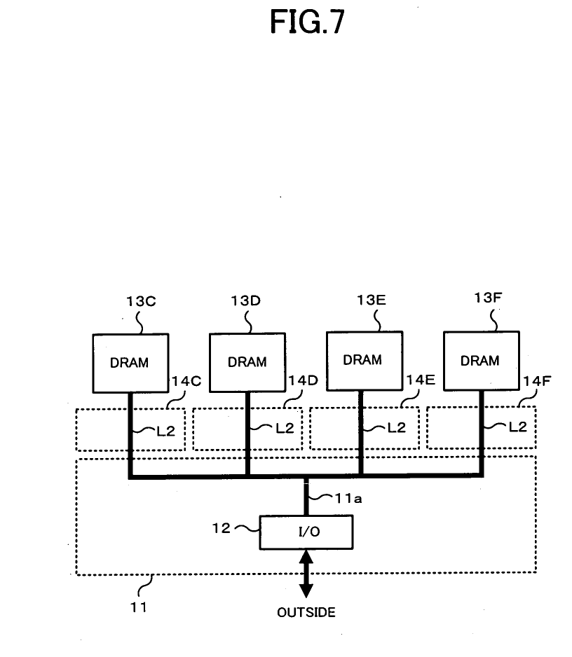

Next, FIG. 7 is a schematic diagram showing a connection configuration of the stacked type memory of the second embodiment. In FIG. 7, the same bus type connection form is adopted as FIG. 4 of the first embodiment. In this case, the basic operation and signal transmission of the interface chip 12 and the DRAM chip 13 are common to FIG. 4. On the other hand, the interface chip 12 is connected from the wiring pattern 11a of the baseboard 11 branching into four directions through the four interposer boards 14 to the four DRAM chips 13. Then, chip select terminals (not shown) of the four DRAM chips 13 enable distribution of a variety of signals to the interface chip 12.

Although, the first and second embodiments show the stacked type memory in which two or four DRAM chips 13 are stacked, it is possible to construct a stacked type memory in which a larger number of DRAM chips 13 are stacked and corresponding interposer boards are provided within a manufacturing limit.

In this embodiment, an implementation suitable for the stacked structure of the DRAM chips 13 and the above-described bus type connection form by optimizing the arrangement of the interposer boards 14 and the wiring structure through the interposer boards 14. First, by paying attention to the arrangement of the interposer board 14, the configuration of this embodiment has a feature that each interposer board 14 extends only to one long side of the rectangle of the DRAM chip 13 and thereby having the inclined portion.

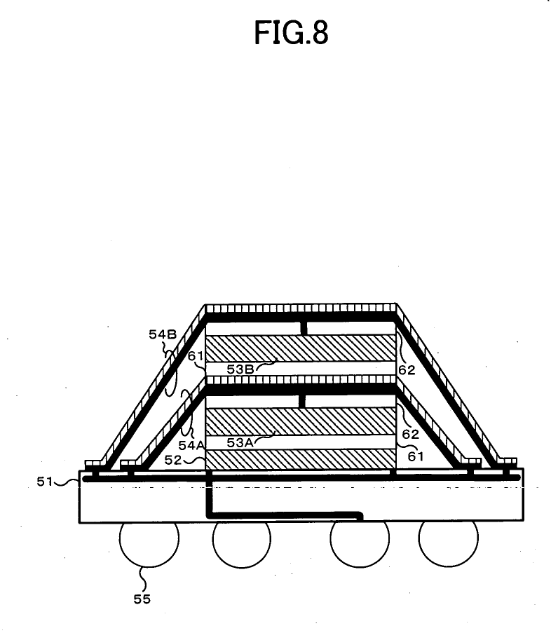

Here, the feature of the wiring structure of this embodiment will be described by showing comparative examples corresponding to this embodiment. In a first comparative example of FIG. 8, a structure including a baseboard 51, an interface chip 52, two DRAM chips 53 (53A, 53B), two interposer boards 54 (54A, 54B), solder balls 55, adhesive layers 61 and a filler 62 is shown, which is basically common to the case of FIG. 2. Meanwhile, a difference in FIG. 8 from FIG. 2 is that the two interposer boards 54 extend to two opposite long sides of the rectangle of the DRAM chip 53. That is, in FIG. 8, the inclined portions of the two interposer boards 54 are disposed on both ends of the top face of the baseboard 11.

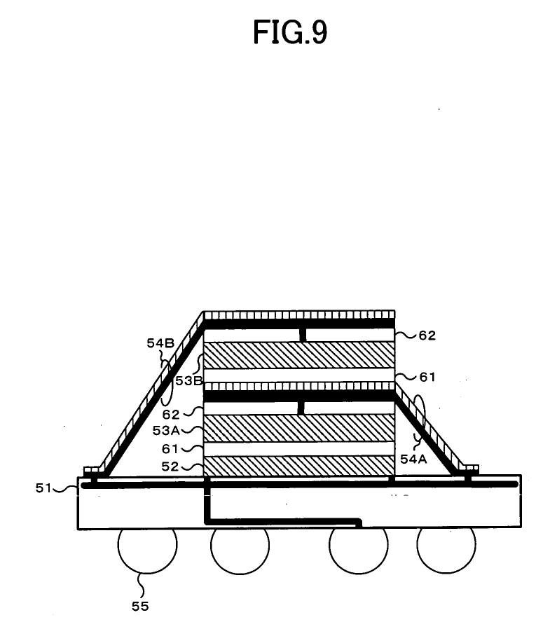

Further, in a second comparative example of FIG. 9, a difference compared to the first comparative example is that each interposer board 54 extends only to one long side of the rectangle of the DRAM chip 53 and the lower and upper interposer boards 54A and 54B extend in opposite directions to each other. Therefore, in FIG. 9, on each end of both sides on the top face of the baseboard 11, the inclined portion of either of interposer boards 54 is disposed.

As evident from comparison of the structures of the first and second comparative examples with FIG. 2, to secure an area for disposing the extended inclined portions of the interposer boards 54 on both sides of the baseboard 51, the size of the interface chip 52 and the DRAM chips 53 need to be sufficiently reduced relative to the size of the baseboard 51. That is, in FIGS. 8 and 9, if the baseboard 51 of the same size as the baseboard 11 of FIG. 2 is used, the size of the DRAM chip 53 needs to be smaller, and if the DRAM chips 53 of the same size as the DRAM chips 13 of FIG. 2 is used, the size of the baseboard 51 needs to be larger. In any case, this structure has a disadvantage for space efficiency. On the contrary, in this embodiment, an advantageous structure for optimizing the size of the stacked type memory including the DRAM chips 13 is achieved.

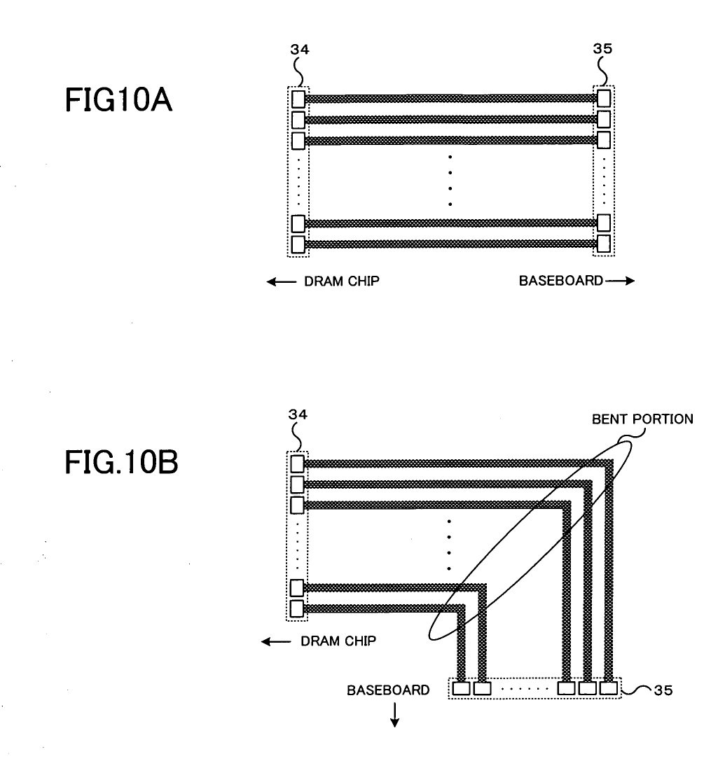

Next, by paying attention to the wiring structure of this embodiment, usability of this embodiment in signal transmission will be described. As described above, a plurality of wires arranged in parallel is used as the wiring pattern of the interposer boards 14 and the baseboard 11 (FIGS. 3A and 3B). The effect of such wiring structure will be described with reference to FIGS. 10A and 10B. FIG. 10A is a diagram showing a plurality of wires arranged in parallel leading to the baseboard 11 through the interposer board 14 of this embodiment and FIG. 10B is a diagram for comparison showing the a plurality of wires having a corner portion halfway.

In the structure of this embodiment, a relation that the plurality of wires is arranged in parallel and with the same length is satisfied as shown in FIG. 10A. The plurality of wires includes power supply wires, ground wires and signal wires. On the other hand, the wiring structure of FIG. 10B is adopted when, for example, the pad row 33 of the DRAM chip 13 and the terminal rows 31 and 32 of the baseboard 11 are arranged at right angle to each other. In the case of FIG. 10B, the corner portion exists on the plurality of wires halfway, and the relation that it is arranged in parallel and with the same length is not satisfied. Generally, since high-speed signal transmission is performed between the interface chip 12 and the DRAM chips 13, the wiring structure is electrically unbalanced between the interface chip 12 and the DRAM chips 13 in the case where the above-described relation is not satisfied, and inductance component of the wires increases thereby causing distortion of transmission waveform. The wiring structure of FIG. 10A can suppress such distortion of the transmission waveform, thereby achieving a wiring structure suitable for high-speed signal transmission compared to FIG. 10B. In addition, the interposer board 14 is bent downward in the vicinity of the boundary of the area R1 shown in FIG. 3A, but the position of the corner portion is perpendicular to the extending direction of the plurality of wires. However the wiring structure of being in parallel and having equal length is maintained, so the problem of FIG. 10B does not arise.

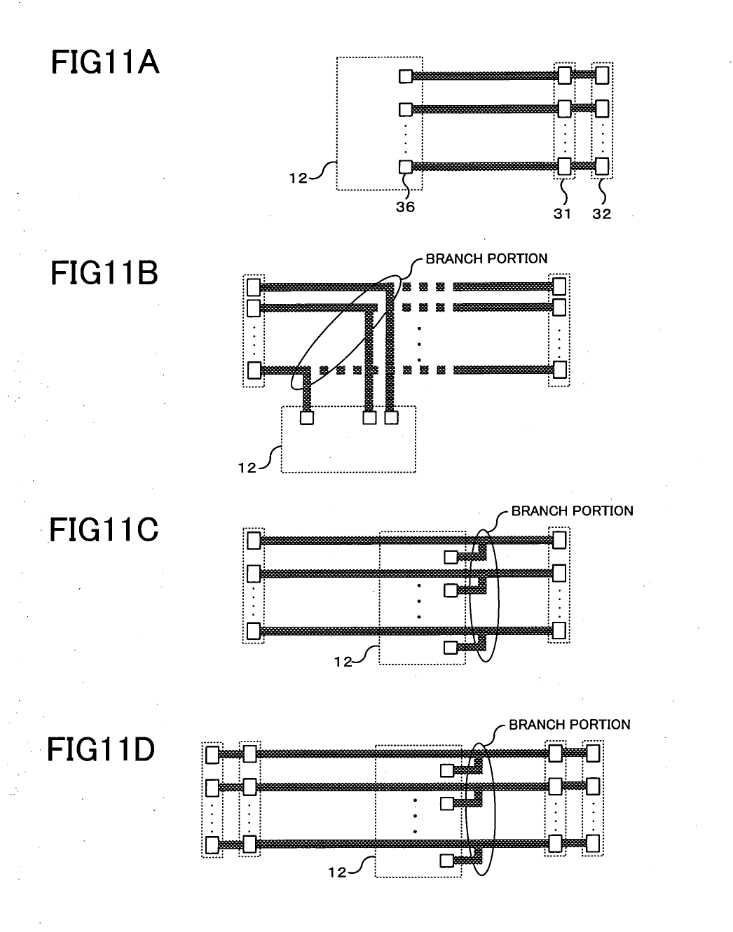

Next, by paying attention to the wiring pattern 11a of the baseboard 11, the effect of the wiring structure of this embodiment will be described using FIG. 11A. FIG. 11A shows schematically the wiring structure including the baseboard 11 having the terminal arrangement shown in FIG. 3B and the interface chip 12. In the wiring structure of FIG. 11A, the terminal rows 31 and 32 connected to the interposer boards 14 and the terminal row 36 connected to the interface chip 12 are connected to each other by a plurality of wires arranged therebetween in parallel and with the same length. This structure can prevent interference between the wires and impedance mismatching, and large wiring area for forming the plurality of wires is not required.

On the contrary, FIGS. 11B to 11D show examples in which the wiring structure of FIG. 11A is not satisfied. The wiring structure of FIGS. 11B and 11C corresponds to a case where the interposer boards 14 are arranged as shown in the second comparative example (FIG. 9), and the terminal rows 31 and 32 are placed at opposite ends of the baseboard 11. In an example of FIG. 11B, the interface chip 12 is arranged at a position shifted from the plurality of wires. The wiring structure of FIG. 11D corresponds to a case where the interposer boards 14 are arranged as shown in the first comparative example (FIG. 8) and two terminal rows are placed at an end of one side while two terminal rows are placed at an end of the other side of the baseboard 11.

The wiring structure of FIGS. 11B to 11D has branch portions on a plurality of wires halfway, through which the terminal row 36 of the interface chip 12 is connected. The plurality of wires is extends to both sides of the interface chip 12, so that the same length wiring is not secured thereby resulting in electrically unbalanced state. In this case, the wires interfere with each other and distortion of transmission waveform is generated due to impedance mismatching at the branch portions, and thus these wiring structures are not suitable for high-speed transmission. Further, increasing the pitch or the length of the wires in order to prevent the interference between the wires causes the wiring area to increase.

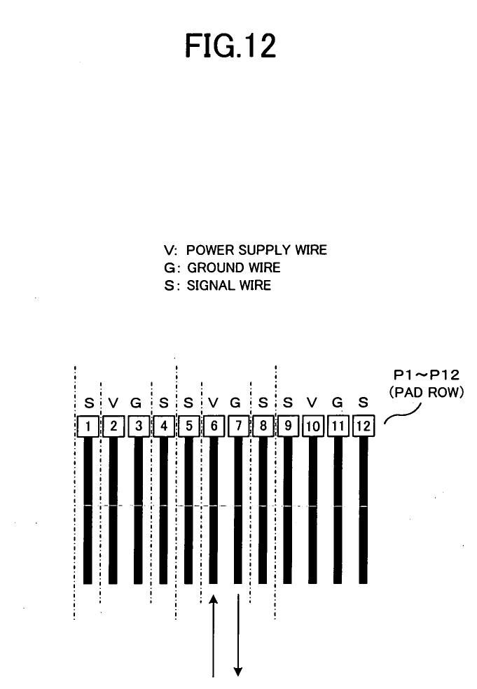

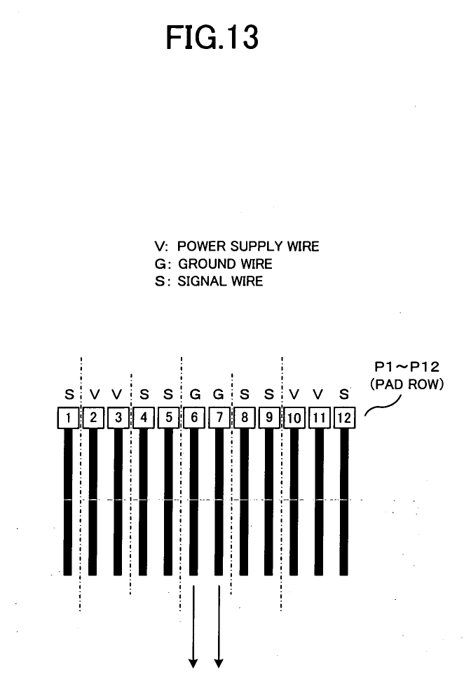

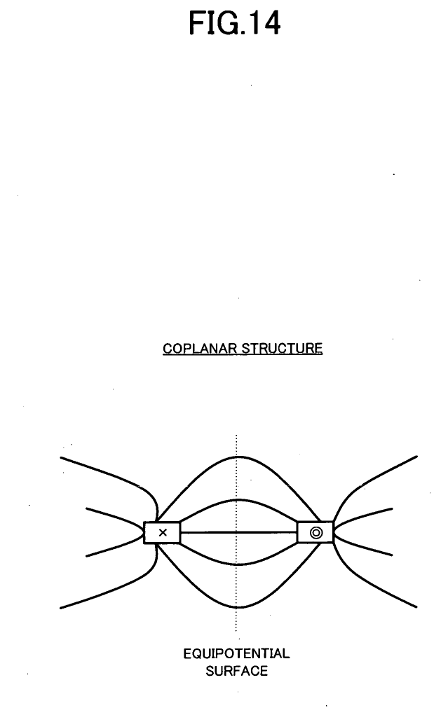

Next, the arrangement pattern of the plurality of wires on the interposer board 14 will be described with reference to FIGS. 12 and 13. As described above, the plurality of wires for connecting between the DRAM chip 13 and the interface chip 12 are classified into the power supply wires, the ground wires and the signal wires. This embodiment achieves a stacked type memory suitable for high-speed signal transmission by specifying the order of the arrangement of the power supply wires, the ground wires and the signal wires. In addition, the power supply wires includes, for example, a wire for supplying power supply voltage Vdd of the DRAM chip 13, the ground wires includes, for example, a wire for supplying reference voltage Vss of the DRAM chip 13, and the signal wires includes, for example, a wire for transmitting address or data for the DRAM chip 13.

FIG. 12 is a diagram showing optimized arrangement pattern of the plurality of wires on the pad row 33 of the DRAM chip 13 of this embodiment and its periphery. FIG. 13 is a diagram showing an example of arrangement pattern without optimization of this embodiment for comparison with FIG. 12. In FIGS. 12 and 13, each pad included in the pad row 33 is given a number expressed as P1 to P12, and of the plurality of wires, each power supply wire is expressed as V, each ground wire is expressed as G and each signal wire is expressed as S.

The arrangement pattern adopted in this embodiment is, as shown in FIG. 12, a pattern in which signal wires S are arranged on both sides of a pair of wires composed of a power supply wire V and a ground wire G pair and this arrangement is repeated. In other words, this is an arrangement pattern in the order SVGS, and each set of pads P1 to P4, P5 to P8 or P9 to P12 of the pad row of FIG. 12 has the SVGS arrangement, which is a pattern having a repeating unit of SVGS. By adopting such an arrangement pattern, return current of the current flowing through the signal wire S flows in the opposite directions to each other in the power supply wire V and the ground wire G (indicated with arrows in the Figure). Accordingly, impedance between the wires of power supply and ground can be reduced so as to reduce simultaneous switching noise or EMI noise which is a problem in signal transmission.

On the contrary, the arrangement pattern shown in FIG. 13 is a pattern in which the two same wires (the power wires V, the ground wires G and the signal wires S) are adjacent to each other. Such an arrangement can be configured effectively because adjacent wires share pads for power supply of ground, but common phase current flows through the adjacent two wires (indicated with arrows in the Figure). Accordingly, impedance of the wires (mainly inductance component) is increased thereby increasing the above-described simultaneous switching noise or EMI noise. The arrangement pattern adopted in this embodiment is more advantageous for improving the noise immunity performance than the general arrangement pattern shown in FIG. 13.

The plurality of wires arranged in parallel according to the arrangement pattern shown in FIG. 12 can be considered as a transmission line having a coplanar structure. FIG. 14 shows an example of the transmission line having the coplanar structure. For example, if adjacent signal wire S and ground wire G form one transmission line, characteristic impedance of the transmission line becomes constant by electrically coupling as shown in FIG. 14. Thus, reflection and crosstalk on the transmission line can be reduced, thereby achieving a wiring structure suitable for high-speed signal transmission.

Further, in this embodiment, a configuration suitable for high-speed transmission to the DRAM chip 13 is achieved by adopting the bus type connection form shown in FIG. 4 or 7. In the case of the first embodiment, connection paths from the interface chip 12 to the DRAM chips 13 are not individually separated but the wiring portion to the terminal row 31 or 32 are shared. Thus, each terminal on the output side of the interface chip 12 is connected to each terminal on the input side of the two DRAM chips 13, thereby approximately doubling the capacitance as compared with separated connection. Generally, the DRAM chips 13 have high drivability, and if capacitance increases by the bus type connection form, signal waveform ringing or the like which is likely to occur due to high drivability in high-speed transmission can be suppressed.

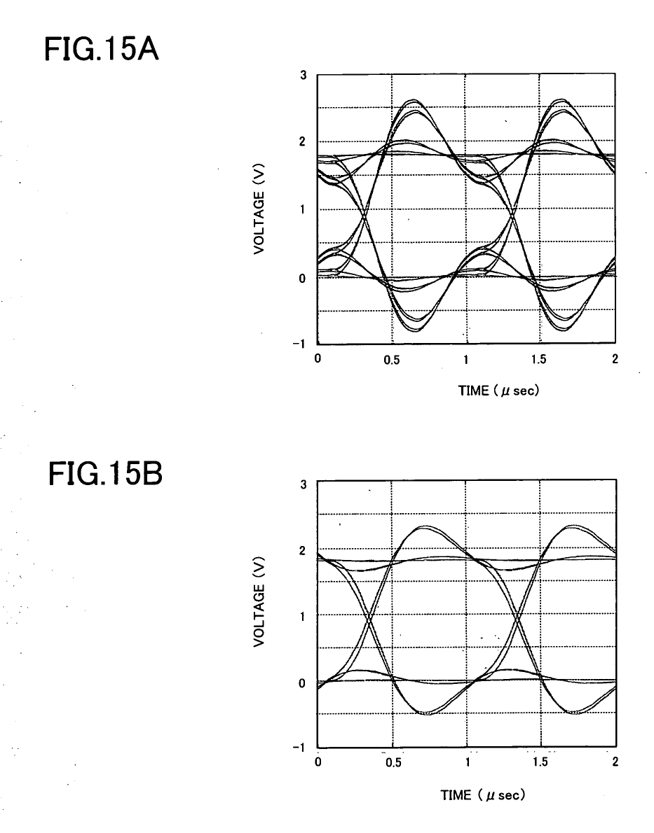

FIGS. 15A and 15B are diagrams showing an analysis result of the operating waveform by simulation in order to confirm the effect of the bus type connection form of this embodiment. In this simulation, a signal waveform when the connecting path to the DRAM chip 13 is replaced with RC model and a predetermined pulse is input. FIG. 15A shows a signal waveform corresponding to the RC model of the separated connection for comparison, in which eye pattern is distorted by the high drivability. On the other hand, FIG. 15B shows a signal waveform corresponding to the RC model of the two DRAM chips 13 of this embodiment, in which distortion of the eye pattern is reduced as compared with FIG. 15A. In FIG. 15B, since capacitance on the input side is larger than that of FIG. 15A, time constant decreases and a rapid change in the waveform is suppressed, so that a stable signal waveform is obtained.

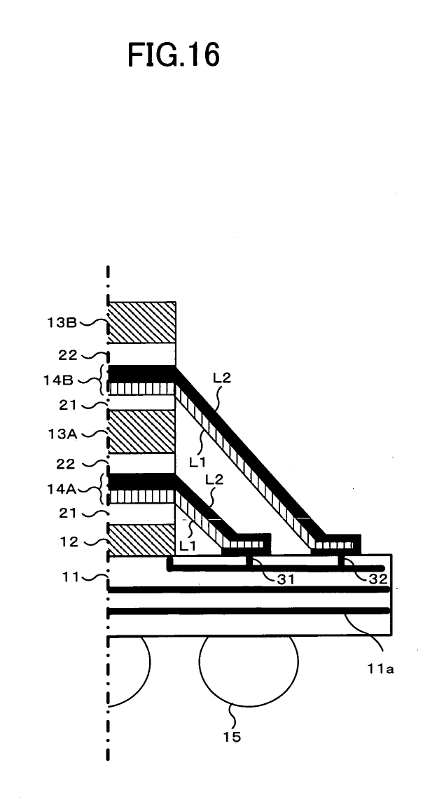

Next, implementation conditions of the stacked type memory of this embodiment will be supplementarily described. As shown in FIG. 2, the DRAM chips 13 are stacked in the face-up structure as described previously and its reason will be described. FIG. 16 shows a state around the periphery of one end of the baseboard 11 in a case of assuming that two DRAM chips 13 are stacked in the face-down structure to construct a semiconductor device. By comparing the structure shown in FIG. 16 with FIG. 2, since the two DRAM chips 13 have the face-down structure, the lower interposer board 14A is placed below the DRAM chip 13A while the upper interposer board 14B is placed below the DRAM chip 13B. That is, the positional relation between the DRAM chips 13 and the interposer board 14 is reversed compared to FIG. 2, and thus the two interposer boards 14 are mounted with their base material L1 facing downward and their wiring layers L2 facing upward.

In order to connect the terminal row 35 (FIG. 3A) of each interposer board 14 to the terminal rows 31 and 32 of the baseboard 11 in such a state, the interposer board 14 needs to be formed with two layers to form the wiring layers L2 on both sides around the terminal row 35, or the interposer board 14 needs to be folded back in the vicinity of the terminal row 35 to fit both bonding surfaces of the terminal row 35 and the terminal rows 31 and 32. However, by each of the methods, the implementation process becomes complicated, and the interposer boards 14 become thicker to increase its stiffness, or stress is induced by bending of the interposer board 14 or the like, thereby causing reduction in reliability and increase in cost.

On the contrary, in this embodiment, since the face-up structure of the DRAM chip 13 is adopted as shown in FIG. 2, in the vicinity of the terminal row 31 of the wiring layer L2 of the interposer board 14, bonding surfaces of the terminal row 31 and the terminal row 35 at the end of the baseboard 11 fit naturally to each other. Accordingly, the interposer boards 14 of this embodiment need to have the wiring layer L2 of one layer and its thickness can be reduced to reduce its stiffness. Further, by stacking the DRAM chips 13 in the face-up structure, heat radiation characteristic of the DRAM chip 13, particularly of the topmost layer, is improved.

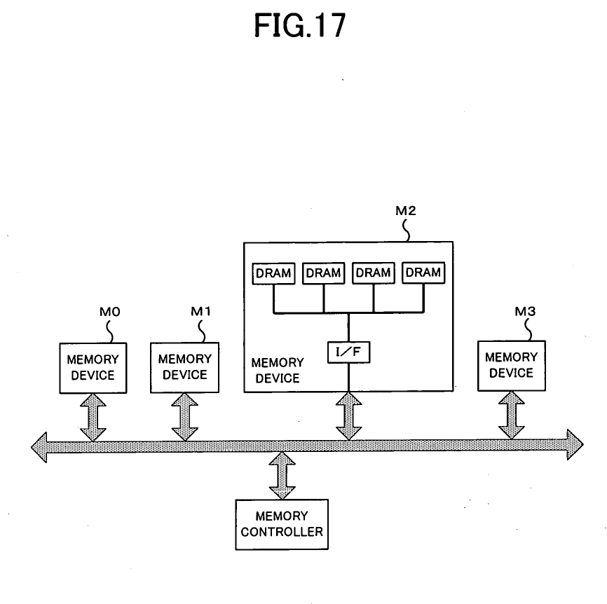

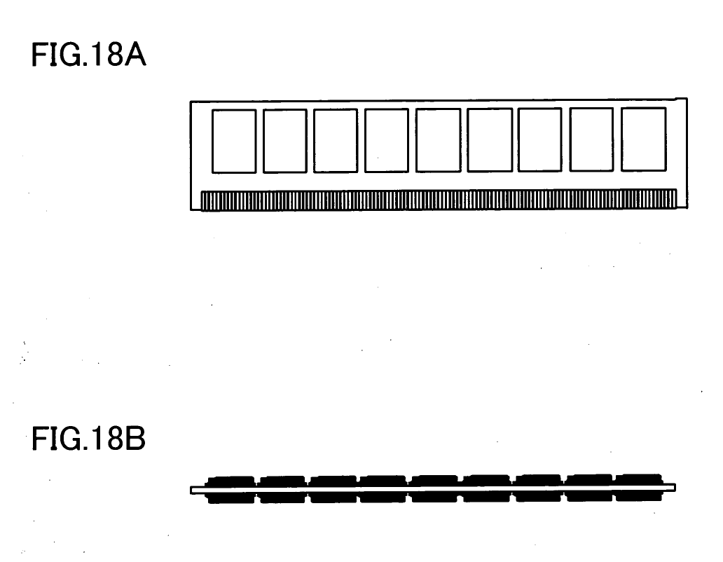

Next, the memory module using the stacked type memories of this embodiment will be described with reference to FIGS. 17 and 18. FIG. 17 shows a block diagram of the memory module composed of a memory controller MC and a plurality of stacked type memories M0 to M3. In FIG. 17, for example, the stacked type memory M2 is constructed according to the second embodiment shown in FIG. 5 and includes the interface chip 12 and four DRAM chips 13. The other stacked type memories M0, M1 and M3 may have the same configuration as the stacked type memory M2 or may have different configuration from each other. The memory controller MC controls operations of the stacked type memories M0 TO M3 through the bus, so that the entire memory module functions as a single large capacity memory. As an example of the appearance of the memory module having the configuration of FIG. 17, FIG. 18A shows a plane view and FIG. 18B shows a side view. In this manner, a thin memory module having a number of external terminals can be constructed and attached to a socket of a board freely.

Although the embodiments of the present invention have been described specifically above, the present invention is not restricted to the above-described embodiments but may be modified within a range not departing from its spirit. For example, although the stacked type semiconductor device of this embodiment is constructed by stacking the plurality of DRAM chips 13 and the interface chip 12, the present invention can be applied to not only this example but also the stacked type semiconductor device equipped with semiconductor chips for various applications. Further, regarding the interposer board 14, the present invention can be applied to without any limitation to the structure or material of this embodiment.

The present invention is not limited to the above described embodiments, and various variations and modifications may be possible without departing from the scope of the present invention.

This application is based on the Japanese Patent application No. 2005-112902 filed on Apr. 8, 2005, entire content of which is expressly incorporated by reference herein.

What is claimed is:

1. A stacked type semiconductor device, comprising:
a baseboard having a terminal row formed at an end in which a plurality of connecting terminals is arranged linearly and having a wiring pattern electrically connected to said plurality of connecting terminals and external terminals;
one or more semiconductor chips having a pad row in which a plurality of pads is arranged linearly in approximately parallel to said terminal row and being stacked on said baseboard; and
one or more interposer boards having a wiring layer including a plurality of wires arranged approximately in parallel with an approximately same length for electrically connecting between each pad of said pad row and each connecting terminal of said terminal row.

2. A stacked type semiconductor device according to claim 1, wherein a flexible board which is formed by combining base material made of resin and said wiring layer is used as said interposer board.

3. A stacked type semiconductor device according to claim 1, wherein said semiconductor chip has a rectangular shape and said pad row is arranged in parallel with a long side direction of said rectangular shape at an approximate center position of said semiconductor chip.

4. A stacked type semiconductor device according to claim 3, wherein said interposer board extends from a position of said pad row to one long side of said semiconductor chip.

5. A stacked type semiconductor device according to claim 4, wherein said plurality of wires includes one or more signal wires, one or more power supply wires and one or more ground wires each connected to a circuit of said semiconductor chip.

6. A stacked type semiconductor device according to claim 5, wherein said signal wire of said interposer board is formed to be a transmission line having a coplanar structure.

7. A stacked type semiconductor device according to claim 6, wherein said plurality of wires is arranged so that a pair of adjacent wires composed of said power supply wire and said ground wire is adjacent to said signal wire.

8. A stacked type semiconductor device according to claim 7, wherein an arrangement pattern of said plurality of wires is a pattern in an order of said signal wire, said power supply wire, said ground wire and said signal wire as a repeating unit, and said plurality of pads of said pad row is arranged according to said arrangement pattern

9. A stacked type semiconductor device according to claim 1, comprising a plurality of said semiconductor chips, and further comprising a plurality of said interposer boards corresponding to a whole or a part of said plurality of semiconductor chips,
wherein a plurality of said terminal row corresponding to said plurality of interposer boards respectively is formed on said baseboard,
and wherein said plurality of interposer boards is arranged in a positional relation in which the nearer said corresponding semiconductor chip is to said baseboard in a stacking direction, the nearer said corresponding terminal row is to an inside of said baseboard in a planar direction.

10. A stacked type semiconductor device according to claim 1, wherein said semiconductor chip is stacked in a face-up structure and said interposer board is arranged so that said wiring layer is opposite to a surface of said semiconductor chip.

11. A stacked type semiconductor device according to claim 3 or 4, wherein a plurality of DRAM chips each having said pad row of a center pad structure are stacked on said baseboard, and an interface chip for controlling data input/output of each said DRAM chip are stacked between said baseboard and said plurality of DRAM chips.

12. A stacked type semiconductor device according to claim 11, wherein said interface chip and said plurality of DRAM chips are connected to each other in a bus type connection form.
